(19) United States
(12) Patent Application Publication
(10) Pub. No.: US 2008/0315943 A1
(43) Pub. Date: Dec. 25, 2008

(54) Anti-Jitter Circuits

(76) Inventor: Michael James Underhill, Surrey (GB)

Correspondence Address: STITES & HARBISON PLLC, 1199 NORTH FAIRFAX STREET, SUITE 900, ALEXANDRIA, VA, 22314, US

(21) Appl. No.: 11/572,600

(22) PCT Filed: Jul. 21, 2005
(86) PCT No.: PCT/GB2005/002864

§ 371 Date: Jul. 28, 2008

(30) Foreign Application Priority Data
Jul. 26, 2004 (GB) 0416627.8

(51) Int. Cl. H03K 5/19; H04J 3/06

(52) U.S. Cl. 327/552; 370/516

(57) ABSTRACT

An anti jitter circuit for reducing time jitter in an input pulse train comprises an integrator, a DC removal circuit and a comparator. The anti jitter circuit also has a feedback loop effective to suppress phase deviation of the output pulse train in response to jitter.

This invention relates to anti-jitter circuits (AJC).

Computing and telecommunications systems operate with internal or external clock signals which facilitate functions such as modulation, demodulation, analogue-to-digital conversion and synchronisation of data streams, for example. Such systems require low phase noise, directly proportional to time jitter. Phase noise or time jitter arises when the position of a pulse in a pulse train is displaced in time from the position expected on the assumption of strict periodicity of the pulse train.

An AJC is a circuit designed to suppress phase noise or time jitter.

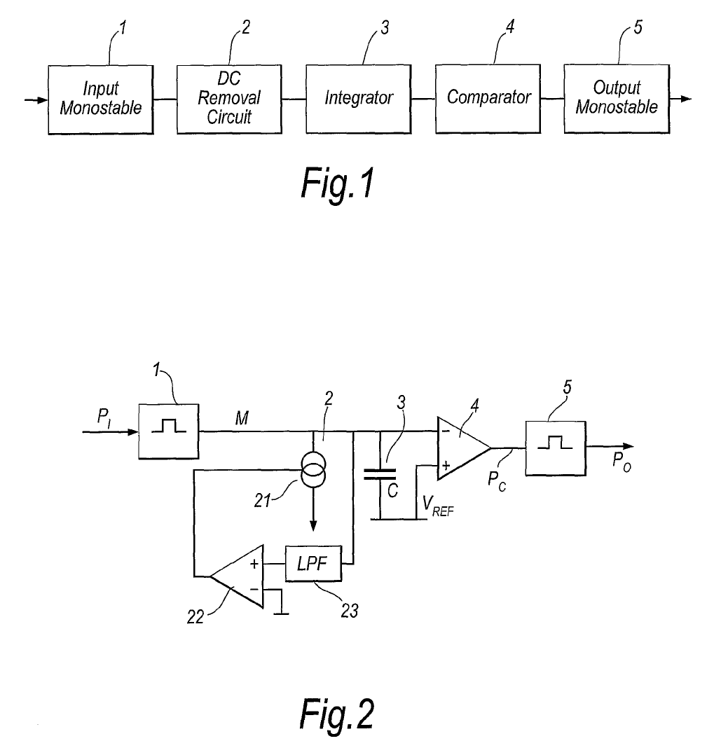

A known AJC is shown in FIGS. 1 and 2. Referring to FIG. 1, the AJC comprises the serial arrangement of an input monostable 1, a DC removal circuit 2, an integrator 3, a comparator 4 and an output monostable 5. FIG. 2 illustrates these components in somewhat greater detail. Referring to FIG. 2, an input pulse train P_{I} is supplied to the input monostable 1 which generates a series of pulses M all of the same length, Tp. The pulses M are supplied to integrator 3, in the form of a capacitor C, via DC removal circuit 2. The function of the DC removal circuit 2 is to remove DC current from pulses M to prevent integrator 3 from drifting towards saturation. In this way, the output of the integrator will have a steady mean DC voltage level.

In this particular example, the DC removal circuit 2 comprises a negative feedback loop including a current source 21, a buffer 22 and a low pass filter 23. Typically, the low pass filter comprises the combination of a resistor R_{F} and a capacitor C_{F}, the voltage of which is supplied to a control input of current source 21 via buffer 22. Integrator 3 integrates pulses M after DC voltage has been removed from the pulses by the DC removal circuit 2 and produces a time varying voltage having a sawtooth waveform S. More specifically, integrator 3 accumulates charge during the interval of each pulse M and discharges during the intervals between pulses. The time varying voltage is compared with a reference voltage V_{REF} which is preferably at or close to the mean DC voltage level of the time varying voltage output by the integrator 3.

The comparator 4 produces a series of output pulses P_{c} whose rising edges occur at periodic intervals Tₒ; that is, whenever the discharge part of the sawtooth waveform S (i.e. the down-slope in this example) crosses the reference voltage V_{REF}. This happens even though one or more pulse of the input pulse train P_{I} might be displaced from its expected position. In these circumstances, the rising edges of output pulses P_{c} have reduced phase noise or time jitter relative to the input pulse train P_{I}.

The output pulses P_{c} are supplied to output monostable 5 which generates an output pulse train Pₒ having the same periodicity as the input pulse train P_{I}, and which has reduced phase noise or time jitter on both the rising and falling edges of the constituent pulses. It will be understood that, alternatively, the discharge part of the sawtooth waveform S may be located on the up-slope and/or the falling edges of output pulses P_{c} may have reduced phase noise or time jitter, these factors being determined by the relative polarities of the AJC components. Furthermore, although the monostable 5 is a convenient means for generating a periodic output pulse train Pₒ, the output pulses P_{c} may themselves provide a useful AJC output and, in these circumstances, the monostable 5 or like circuitry may be omitted.

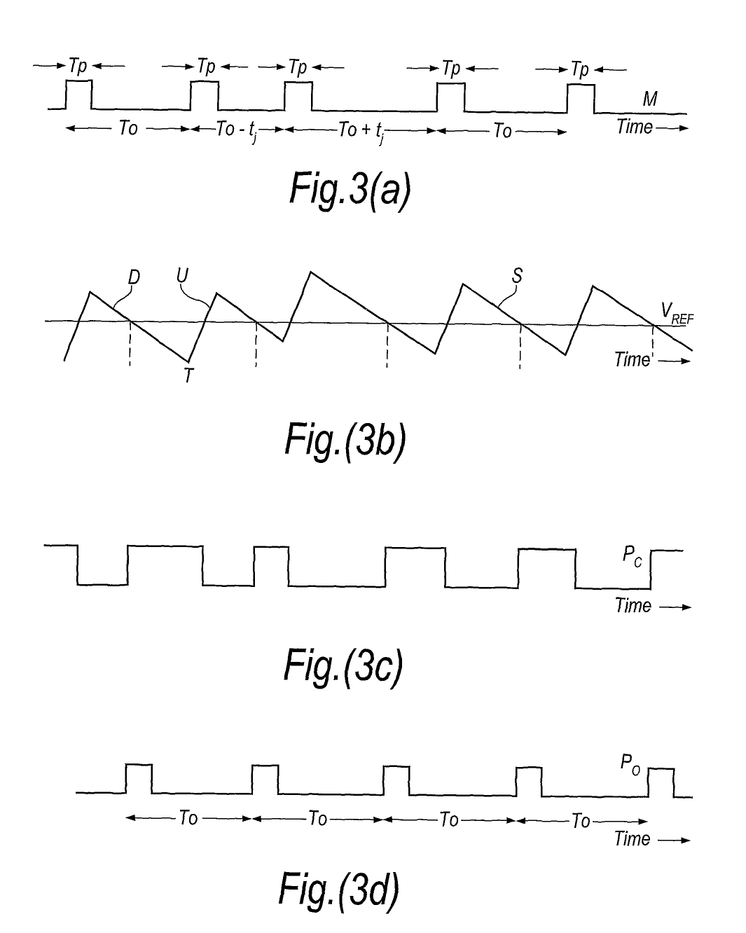

The jitter reducing action of this known AJC can be understood with reference to the timing charts of FIGS. 3a to 3d. FIG. 3a shows a pulse train having five pulses M generated by the input monostable 1. The pulses all have the same width and height; that is, the same area. This pulse train is subject to time jitter, one of the pulses being misplaced relative to the others by time tⱼ.

FIG. 3b shows the sawtooth waveform S output by integrator 3 and FIG. 3c shows the output pulses P_{c} output by comparator 4. Provided the DC removal circuit 2 is operating satisfactorily so that the mean DC voltage of the sawtooth waveform S is reasonably stable, the times at which comparator 4 switches on the down-slope of the sawtooth waveform S are unaffected by the time jitter tⱼ on the central pulse of pulses M. Thus, the rising edges of output pulses P_{c}, and both the rising and falling edges of output pulse train Pₒ output by output monostable 5, shown in FIG. 3d, are completely jitter free.

In effect, any phase deviation of each incoming pulse is converted to voltage, which is subtracted from another voltage representing averaged phase. The resultant voltage is then converted linearly into a time delay which cancels the original phase deviation repositioning the corresponding output pulse with a net phase delay, but reduced phase error in relation to preceding pulses.

In this example, the low pass filter of the DC removal circuit 2 is connected to the integrator. Alternatively, the low pass filter could be connected to the comparator output.

The DC removal circuit 2 has a finite jitter cut-off frequency. Below the cut-off frequency time jitter is not detected and so cannot be reduced or cancelled. In a practical AJC of the kind described jitter cancellation will not be perfect at all frequencies and some residual jitter will be present at the output, especially at low jitter frequencies.

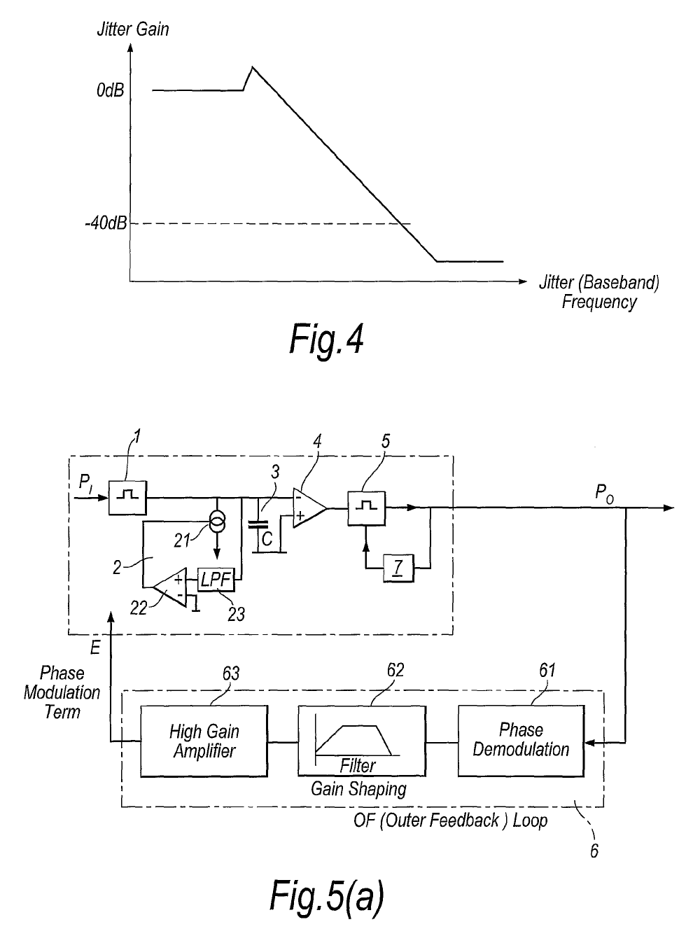

FIG. 4 shows a typical second order low pass characteristic to the jitter transfer function of the described AJC. This shows that jitter is not suppressed at low jitter frequencies.

A further problem associated with the described AJC stems from the open-loop nature of the jitter suppression and also intrinsic noise processes in the AJC.

It is an object of the invention to provide an AJC which at least alleviates these problems.

According to the invention there is provided an anti-jitter circuit for reducing time jitter in an input pulse train comprising:
an integrator for integrating pulses of, or pulses derived from said input pulse train to produce a time varying voltage, the integrated pulses being of equal area,
DC removal means for removing DC signal from said pulses before the pulses are integrated by the integrator whereby the mean of said time varying voltage is substantially steady, a comparator for comparing said time varying voltage with a reference to generate output pulses as a result of the comparison, and
a feedback loop effective to suppress phase deviation of said output pulses in response to jitter.

Preferably the feedback loop has a gain not less than 30 dB, and typically 60 dB.

It has been found that provision of a feedback loop has an unexpected, remarkably beneficial effect. More specifically, it is found that jitter suppression is achievable at lower frequencies and that the effect of intrinsic noise in the AJC components may be much reduced.

Embodiments of the invention are now described, by way of example, with reference to the accompanying drawings, of which:

FIG. 1 is a schematic representation of a known AJC,

FIG. 2 is a more detailed block schematic representation of the AJC shown in FIG. 1,

FIGS. 3a to 3d show waveforms useful in understanding operation of the AJC shown in FIGS. 1 and 2,

FIG. 4 shows a second order low pass filter characteristic to the jitter transfer function for the known AJC shown in FIGS. 1 and 2,

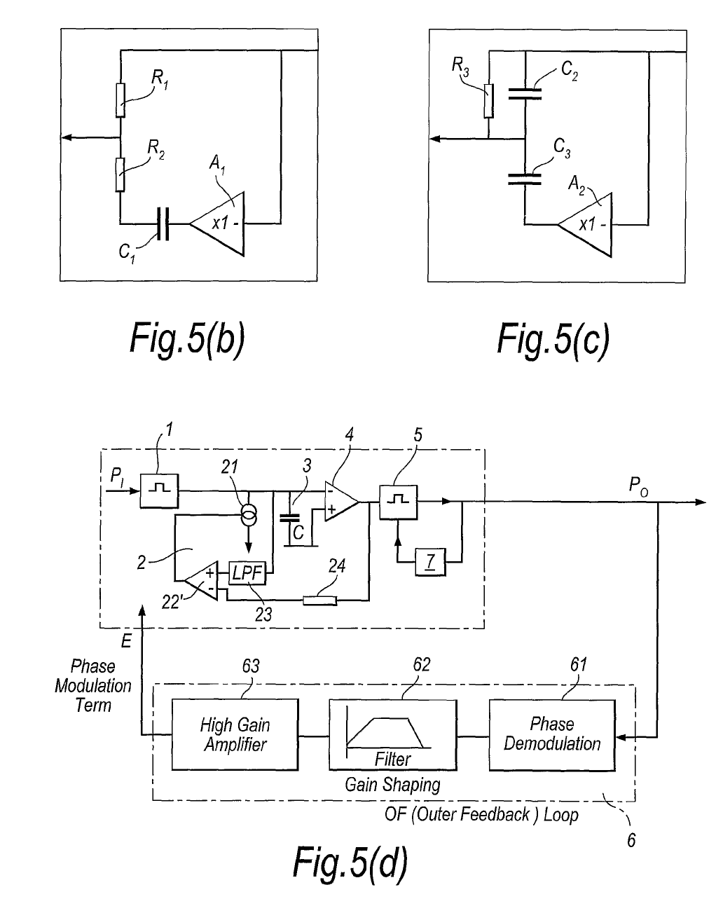

FIG. 5(a) is a block schematic representation of an AJC according to the invention,

FIGS. 5(b) and 5(c) show two examples of bridge feedback circuits which form part of a filter in the feedback loop of the AJC shown in FIG. 5(a),

FIG. 5(d) shows a slope compensation arrangement,

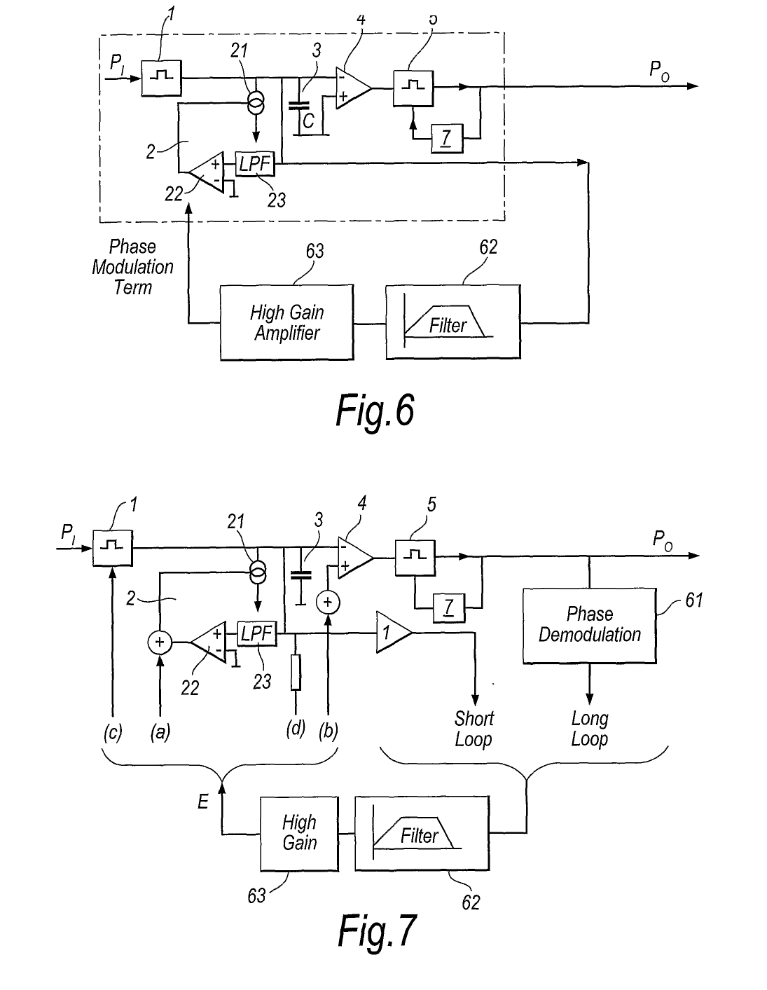

FIG. 6 is a block schematic representation of another AJC according to the invention,

FIG. 7 illustrates different points in the AJC's of FIGS. 5 and 6 where error signal can be applied,

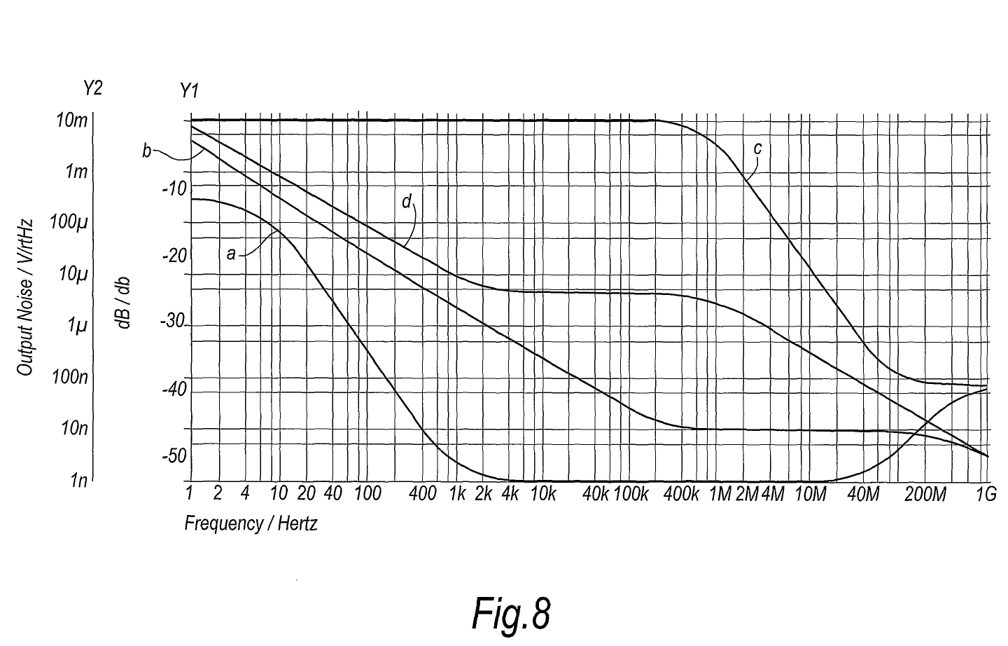

FIG. 8 shows plots of jitter suppression and intrinsic noise as a function of jitter frequency for an AJC according to the invention and a known AJC, and

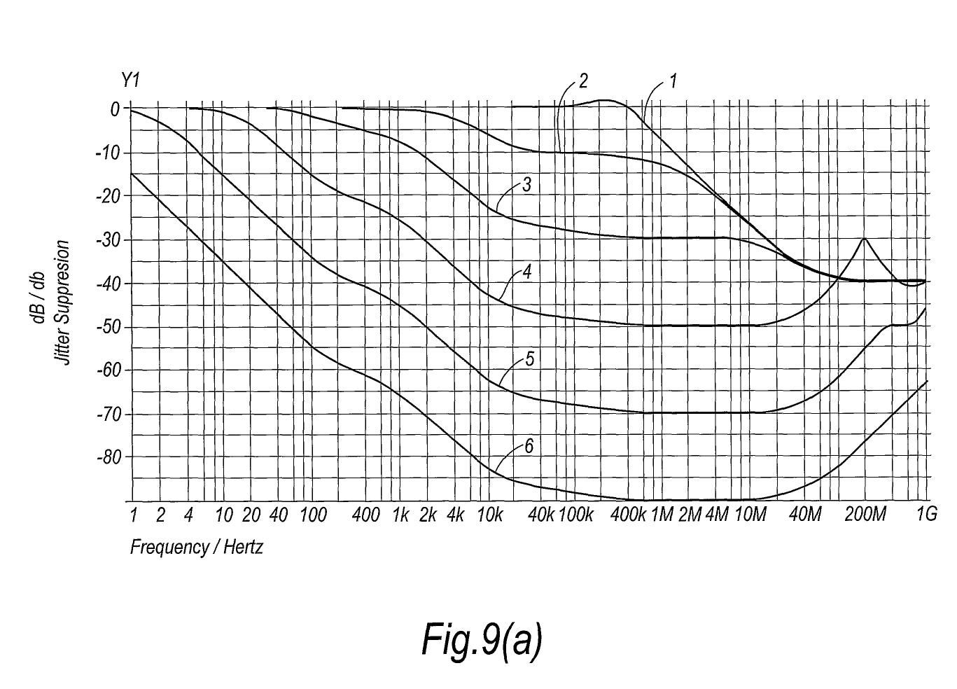

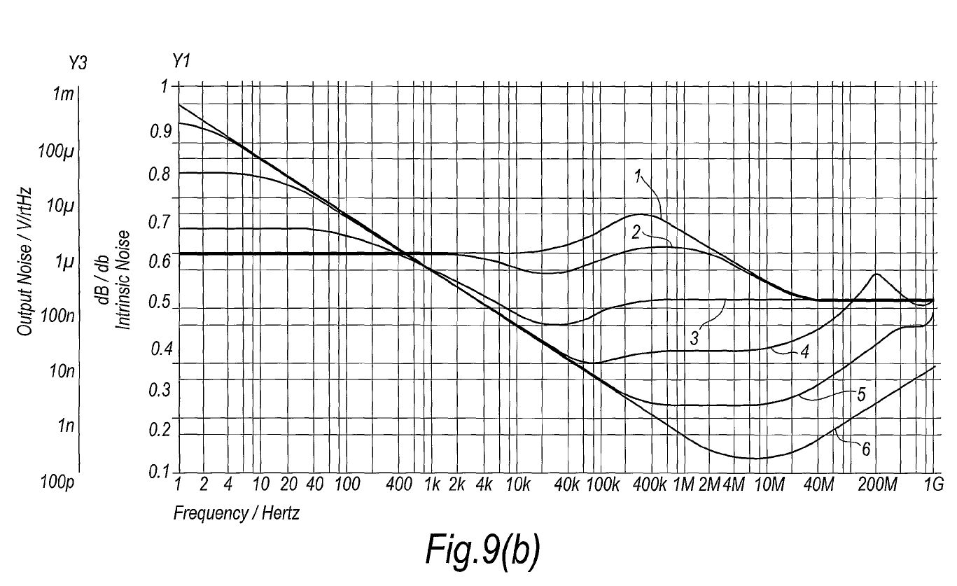

FIGS. 9(a) and 9(b) respectively show plots of jitter suppression and intrinsic noise as a function of jitter frequency for different feedback loop gains.

Referring now to FIG. 5(a), the AJC has several components in common with the known AJC described with reference to FIGS. 1 to 4, and these components are ascribed like reference signs.

In accordance with the invention, the AJC also includes a feedback loop 6 whose function is to suppress phase deviation of the output pulses Pc in response to jitter.

In this embodiment, feedback loop 6 comprises the serial arrangement of a phase demodulator 61, filter 62 and an amplifier 63. In an alternative arrangement, amplifier 63 could be positioned upstream of filter 62 or could consist of two parts positioned to either side of filter 62. Likewise, filter 62 could consist of two parts; for example, a low pass filter part and a high pass filter part. The demodulator 61 is connected to the output monostable 5 and receives output pulse train Pₒ. The demodulated signal (voltage or current) is supplied to filter 62 which in this embodiment has the form of a bandpass filter. The response characteristic of the bandpass filter is so shaped as to substantially attenuate frequencies at or close to DC. In this way, the feedback loop does not dominate the function of DC removal circuit 2. The bandpass filter also substantially attenuates the carrier frequency so that only jitter baseband frequencies below, typically half the carrier frequency are fed back with a loop gain of greater than unity. With this arrangement, the DC removal circuit 2 dominates in controlling the DC operating point whereas the feedback loop dominates in suppressing jitter and instabilities at higher frequencies can be removed. In general, the response characteristic of the filter can be tailored to suit optimal rejection in a desired jitter frequency range.

FIGS. 5(b) and 5(c) show two examples of bridge feedback circuits which may form part (e.g. the low pass filter part) of filter 62 and can be used to attenuate the carrier frequency, although alternative attenuation circuits will be readily envisaged by those skilled in the art.

The bridge feedback circuit shown in FIG. 5(b) comprises two identical resistors R₁ and R₂, a capacitor C₁ and an amplifier A₁ which applies a negative unity gain to a received input. At high frequencies, capacitor C₁ is short-circuited and the input is divided equally between the two resistors giving a null output. At low frequencies, the impedance of capacitor C₁ becomes significant and so the input passes to the output via resistor R₁ with no significant attenuation. The cut-off frequency of the circuit is given by the expression ¼πRC, where R is the resistance of both resistors and C is the capacitance of the capacitor, and this is set at a fraction of the carrier frequency, typically, ½.

The bridge circuit shown in FIG. 5(c) comprises two identical capacitors C₂, C₃, a resistor R₃ and an amplifier A₂ which, again, applies a negative unity gain to a received input. At high frequency, the two capacitors have low impedance, and so the input is divided equally between the capacitors, giving null output. At low frequencies, the impedance of the capacitors becomes significant and the input passes to the output via the resistor R₃. Again, the cut-off frequency is given by the expression ¼πRC, where R is the resistance of resistor R₃ and C is the capacitance of both capacitors, and this is typically set at a fraction of the carrier frequency, typically, ½.

The filter output is supplied to amplifier 63 which applies gain. In this particular embodiment, the gain of feedback loop 6 is about 60 dB. However, as will be described hereinafter different gain values are also useful.

The amplified output is compared with a DC reference level to produce an error signal E which is the inverse of the detected jitter.

As will be described in greater detail hereafter, the error signal E can be applied at different attenuation points in the AJC with a view to reducing or eliminating jitter. The phase demodulator 61 could be of any suitable form; a monostable (e.g. monostable 5) followed by a low pass filter, or the phase detector of an analogue phase-locked loop or the core part of an AJC; that is, an AJC of the kind described with reference to FIGS. 1 and 2, but excluding the comparator and the output monostable. As already explained, the core part of an AJC i.e. the d.c removal circuit and the integrator involves phase-to-voltage conversion and so, in effect, operates as a phase demodulator.

Referring to FIG. 3(b) of the drawings, each down-slope D of the sawtooth waveform S may depart from linearity (in the upward sense) just before the point of transistor T to the next up-slope U. Such non-linearity may adversely affect the effectiveness of the anti-jitter circuit.

In a preferred embodiment, shown in FIG. 5(d) of the drawings, buffer 22 is replaced with a summing amplifier 22′ and a feedback loop F is connected between the output of comparator 4 and one input of the summing amplifier, another input being connected to low pass filter 23. The feedback loop F includes a resistor 24 having a preset resistance. The effect of the feedback loop F is to increase the discharge current supplied by current source 21 after down-slope D has crossed the reference voltage V_{REF} and the comparator 4 has switched, thereby significantly reducing any afore-mentioned non-linearity of the down-slope. The resultant slope compensation gives rise to improved suppression of phase noise or time jitter, particularly when the gain of feedback loop 6 has a relatively low value. e.g. no greater than 30 dB. Such slope compensation may also be used in conventional anti-jitter circuits such as that shown in FIG. 2 in order to achieve improved suppression of phase noise or time jitter.

FIG. 6 shows another embodiment of an AJC in accordance with the invention. As with the embodiments of FIGS. 5a to 5d, components that are in common with the known AJC of FIGS. 1 to 4 are ascribed like reference signs.

In this embodiment, the filter 62 is connected directly to the output capacitor of integrator 3 and no phase demodulator is needed. Alternatively, the filter 62 could be connected to the output of comparator 4. This arrangement is less accurate than the arrangements of FIGS. 5a to 5d because any phase deviation added downstream of the point of connection will not be detected or suppressed. Slope compensation, described with reference to FIG. 5(d) may also be applied to the embodiments described with reference to FIG. 6.

FIG. 7 illustrates different points in the AJC's of FIGS. 5(a) and 6 where the error signal E can be applied with a view to reducing or eliminating jitter. Examples of such points are referenced (a) to (d) in FIG. 7. In the case of point (a) the error signal is applied as an incremental current to integrator 3. This has the effect of modulating with the integral of phase. In the case of point (b) the error signal is applied as a voltage offset to the comparator 4. This has the effect of modulating with phase directly. In the case of point (c) the error signal is applied as a control signal varying the charge delivered by the input monostable 1. Again, this modulates with the integral of phase. Finally, in the case of point (d), the error signal is applied to the integrator 3 via a resistor.

In a yet further embodiment the DC removal function is carried out by the feedback loop instead of a separate DC removal circuit 2. To that end, filter 62 of the feedback loop has a finite DC frequency response and the low pass filter 23 is eliminated.

In practice, the output pulse train Pₒ may contain phase noise or time jitter due to noise in the output monostable 5 itself. Furthermore, any such phase noise or time jitter on the rising edges of the output pulse train Pₒ will be independent of any phase noise or time jitter on the falling edges of the output pulse train Pₒ. In these circumstances, the anti-jitter circuits described with reference to FIGS. 5 to 7 may not adequately suppress phase noise or time jitter on both the rising and falling edges of the output pulse train Pₒ. More specifically, although the described circuits are effective to suppress phase noise or time jitter on one type of edge (the rising edges in the described embodiments), they may not adequately suppress phase noise or time jitter simultaneously present on another type of edge (the falling edges in the described embodiment) due to the presence of noise in the output monostable 5.

In a preferred modification of the circuits described with reference to FIGS. 5 to 7, the mark-space ratio of the output pulse train Pₒ is locked at a fixed value (e.g. 50:50) with a view to alleviating this problem. This may be implemented by different alternative means known to those skilled in the art. In this embodiment, the output mark-space ratio is locked using a mark-space feedback block 7 connected between control and output terminals of the output monostable 5. The locking bandwidth should be as high as possible, but is preferably at least as high as that of feedback loop 6.

The feedback block 7 may be a bridge feedback circuit of the kind described with reference to FIGS. 5(b) and 5(c).

FIG. 8 is a typical plot of jitter suppression (curve a) and intrinsic noise (curve b) as a function of jitter frequency for an AJC according to the invention. These plots are compared with corresponding plots of jitter suppression (curve c) and intrinsic noise (curve d) obtained using a known AJC of the kind described with reference to FIGS. 1 to 4. A comparison of curves a and c clearly demonstrates that an AJC according to the invention has jitter suppression which extends to much lower jitter frequencies. Similarly, a comparison of curves b and d demonstrates that an AJC according to the invention has much reduced intrinsic noise. Furthermore, an AJC according to the invention enables a relatively low jitter cut-off frequency to be attained even if the total capacitance of all capacitors in the circuit is much smaller that that of a known AJC. In a conventional AJC of the kind described with reference to FIGS. 1 to 3 the low pass filter in the DC removal circuit 2 may include a relatively large capacitor, typically 100 times that of integrator capacitor C, in order to minimise or eliminate an undesirable sharp peak shown in the characteristic of FIG. 4. In practice, provision of such a capacitor is costly, especially if it needs to be installed on-chip. Preferred embodiments of the invention enable the undesirable sharp peak to be minimised or eliminated without the need for a relatively large capacitance.

The feedback loop 6 may also be effective to compensate for non-linearities in the AJC circuit. This means that the circuit is capable of operating at higher frequencies that would otherwise be excluded.

The extent of jitter suppression and the intrinsic noise level depend upon the gain of the feedback loop. FIG. 9(a) shows a plot of jitter suppression (in dB) as a function of jitter frequency for different gain values; that is, a gain of 10 dB (curve 2), 30 dB (curve 3), 50 dB (curve 4), 70 dB (curve 5) and 90 dB (curve 6). Curve 1 shows a plot of jitter suppression as a function of jitter frequency attained if the feedback loop is omitted. As curve 1 shows, there is no significant suppression at frequencies below about 400 kHz. Curves 2 to 6 show the effect of the feedback loop for different gain values. Suppression increases, and extends to progressively lower jitter frequencies as a function of increasing gain.

FIG. 9(b) shows a plot of intrinsic or internal noise as a function of jitter frequency for the same gain values. At frequencies greater than about 400 Hz the noise level progressively decreases as a function of increasing gain. However, at very low frequencies i.e. below about 400 Hz this trend is reversed; that is, the noise level progressively increases as a function of increasing gain. In this very low frequency range the noise level is never greater than about 6 dB per octave line, and for most practical systems this is acceptable.

Bearing these curves in mind, the optimum gain is not less than 30 dB, and is preferably about 60 dB, although very useful improvements can be obtained at gain less than 30 dB.

At a gain of about 50 dB improvements in intrinsic noise and suppression at the lowest jitter frequency have become very useful. However, instability of the feedback system has set in as instanced by the upward kink in curves 4 of FIGS. 9(a) and 9(b) at about 200 MHz. In preferred embodiments this instability may be readily removed by suitably shaping the filter response of the feedback loop. This can be arranged by reducing the loop gain at and around the carrier frequency, as already described with reference to FIGS. 5(c) and 5(d). The instability gain point will be higher at higher carrier frequencies (pro rata) and so less carrier frequency gain reduction would be needed.

1. An anti-jitter circuit (AJC) for suppressing time jitter in an input pulse train comprising,
an integrator for integrating pulses of, or pulses derived from said input pulse train to produce a time varying voltage, the integrated pulses being of equal area,
DC removal means for removing DC signal from said pulses before the pulses are integrated by the integrator whereby the mean of said time varying voltage is substantially steady,
a comparator for comparing said time varying voltage with a reference to generate output pulses as a result of the comparison, and
a feedback loop effective to suppress phase deviation of said output pulses in response to jitter.

2. An anti-jitter circuit as claimed in claim 1 wherein said feedback loop includes a filter having a response characteristic dependent on jitter frequency and amplification means for applying gain to an output of the filter to generate an error signal.

3. An anti-jitter circuit as claimed in claim 2 wherein said filter is a bandpass filter.

4. An anti-jitter circuit as claimed in claim 2 wherein said filter includes a bridge feedback circuit suitable for attenuating the carrier frequency of the AJC.

5. An anti-jitter circuit as claimed in claim 4 wherein said bridge feedback circuit includes a pair of identical resistors or a pair of identical capacitors.

6. An anti-jitter circuit as claimed in claim 2 wherein said error signal is applied as current to said integrator.

7. An anti-jitter circuit as claimed in claim 6 wherein said error signal is applied to said integrator via a resistor.

8. An anti-jitter circuit as claimed in claim 2 wherein said error signal is applied to modify said reference.

9. An anti-jitter circuit as claimed in claim 2 including pulse delivery means for receiving said input pulse train and, in response thereto, delivering charge pulses to said integrator, and said error signal is applied to the pulse delivery means to control delivery of the charge pulses.

10. An anti-jitter circuit as claimed in claim 2 wherein said feedback loop includes a phase demodulator coupled between said comparator and said filter.

11. An anti-jitter circuit as claimed in claim 10 wherein said phase demodulator is coupled to the comparator via an output monostable.

12. An anti-jitter circuit as claimed in claim 2 wherein said filter is connected to an input of said integrator.

13. An anti-jitter circuit as claimed in claim 2 wherein said filter is arranged to attenuate the carrier frequency of the AJC such that the loop gain at and around the carrier frequency is less than unity.

14. An anti-jitter circuit as claimed in claim 1 wherein said feedback loop has a gain of not less than 30 dB.

15. An anti-jitter circuit as claimed in claim 14 wherein said feedback loop has a gain of about 60 dB.

16. An anti-jitter circuit as claimed in claim 1 including an output monostable.

17. An anti-jitter circuit as claimed in claim 16 wherein the output monostable has a mark-space ratio locked to a fixed value.

18. An anti-jitter circuit as claimed in claim 1 including a slope compensation feedback loop connected between said DC removal means and an output of said comparator whereby to reduce non-linearity of said time varying voltage.

19. An anti-jitter circuit as claimed in claim 1 wherein said feedback loop includes said DC removal means.

20. An anti-jitter circuit for suppressing time jitter in an input pulse train comprising,
an integrator for integrating pulses of, or pulses derived from said input pulse train to produce a time varying voltage, the integrated pulses being of equal area,
a comparator for comparing said time varying voltage with a reference to generate an output pulse train as a result of the comparison, and
a feedback loop effective to remove DC signal from said pulses before the pulses are integrated by the integrator whereby the mean of said time varying voltage is substantially steady and to suppress phase deviation of the output pulse train in response to jitter.
